(19) United States
(12) Patent Application Publication
(10) Pub. No.: US 2020/0182124 A1
(43) Pub. Date: Jun. 11, 2020

(54) AUTOMOTIVE ELECTRONIC SENSOR ASSEMBLY TEMPERATURE REGULATION SYSTEM

(71) Applicant: Continental Automotive Systems, Inc., Auburn Hills, MI (US)

(72) Inventor: James Robert Massie, Santa Barbara, CA (US)

(73) Assignee: Continental Automotive Systems, Inc., Auburn Hills, MI (US)

(21) Appl. No.: 16/711,177

(22) Filed: Dec. 11, 2019

Related U.S. Application Data
(60) Provisional application No. 62/777,996, filed on Dec. 11, 2018.

(51) Int. Cl. F01P 3/20; B60K 11/04; F01P 11/04; F25B 21/02; G01S 7/481; H05K 7/20

(52) U.S. Cl. CPC F01P 3/20; B60K 11/04; F01P 11/04; F25B 2321/0252; G01S 7/4813; H05K 7/20254; F25B 21/02

(57) ABSTRACT

An automotive electronic sensor assembly includes a light source configured to generate light into a field of view. A detector is configured to receive light reflected off an object in the field of view. The assembly also includes a temperature regulation system. The temperature regulation system includes a thermoelectric cooler coupled to the automotive electronic sensor assembly and a heat exchanger coupled to the thermoelectric cooler and including a passage for accommodating fluid from a cooling system of a vehicle.

### CROSS REFERENCE TO RELATED APPLICATION

This application claims the benefit of provisional patent application No. 62/777,996, filed Dec. 11, 2018, which is hereby incorporated by reference.

### TECHNICAL FIELD

The technical field relates generally to temperature regulation system in an automotive electronic sensor assembly.

### BACKGROUND

Some automotive electronic sensor assemblies, e.g., flash lidar sensor assemblies, generate heat and/or have components that will not perform properly at temperatures which are excessive and/or exceed thermal tolerances/specifications. To compensate, packaging may include bulky heat sinks to dissipate heat. Concurrently, and adversely, automotive manufacturers are demanding smaller and/or lighter sensor assemblies.

As such, there is a need for alternative cooling techniques for automotive electronic sensor assemblies. Furthermore, other advantages and benefits may be realized with a complete reading of the specification and figures.

### SUMMARY

In one exemplary embodiment, a temperature regulation system for an automotive electronic sensor assembly includes a thermoelectric cooler coupled to the automotive electronic sensor assembly. The system also includes a heat exchanger coupled to the thermoelectric cooler, the heat exchanger including a passage for accommodating fluid from a cooling system of a vehicle.

In one exemplary embodiment, an automotive electronic sensor assembly includes a light source configured to generate light into a field of view. A detector is configured to receive light reflected off an object in the field of view. The assembly also includes a temperature regulation system. The temperature regulation system includes a thermoelectric cooler coupled to the automotive electronic sensor assembly and a heat exchanger coupled to the thermoelectric cooler and including a passage for accommodating fluid from a cooling system of a vehicle.

In one exemplary embodiment, a vehicle includes an internal combustion engine. The engine defines a cooling jacket extending to an engine cooling inlet and an engine cooling outlet. A cooling system is coupled to the internal combustion engine. The cooling system includes a radiator having a radiator inlet and a radiator outlet. A first hose connects the engine cooling outlet to the radiator inlet and a second hose connects the radiator outlet to the engine cooling inlet. A fluid pump is connected to one of the hoses for pumping fluid therethrough. The vehicle also includes an electronic sensor assembly for sensing an environment proximate the vehicle. The assembly includes a thermoelectric cooler. The thermoelectric cooler includes a first side coupled to the electronic sensor, a second side, and a plurality of semiconductors disposed between the sides. A heat exchanger is coupled to the second side of the thermoelectric cooler. The heat exchanger includes an inlet port for receiving fluid from the cooling system of the internal combustion engine and an outlet port for returning fluid to the cooling system of the internal combustion engine.

### BRIEF DESCRIPTION OF THE DRAWINGS

Other advantages of the disclosed subject matter will be readily appreciated, as the same becomes better understood by reference to the following detailed description when considered in connection with the accompanying drawings wherein:

FIG. 1 is a diagrammatic perspective view of a temperature regulation system of a vehicle and an automotive electronic sensor assembly according to one exemplary embodiment;

FIG. 2 is a perspective view of the automotive electronic sensor assembly according to one exemplary embodiment;

FIG. 3 is a diagrammatic view of a heat exchanger according to one exemplary embodiment; and

FIG. 4 is a diagrammatic view of the cooling system of the vehicle according to one exemplary embodiment.

### DETAILED DESCRIPTION

Referring to the Figures, wherein like numerals indicate like parts throughout the several views, a temperature regulation system 100 for an automotive electronic sensor assembly 102 is shown and described herein.

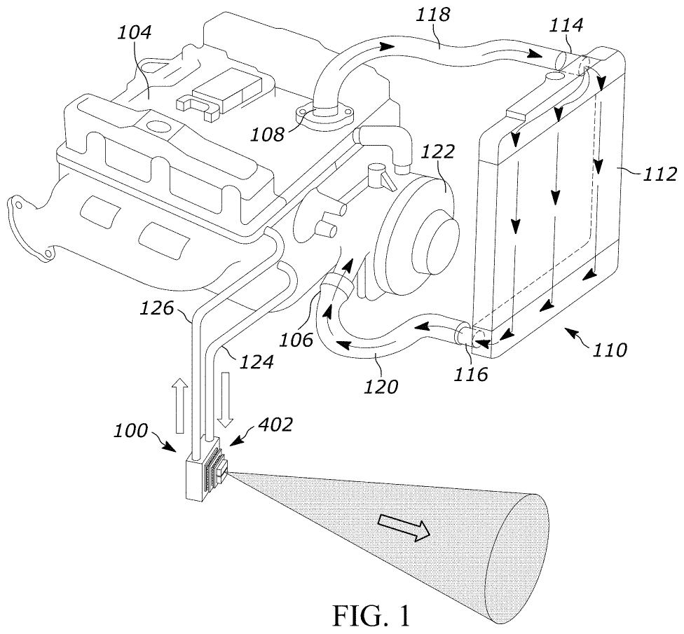

In the embodiment shown in FIG. 1, the temperature regulation system 100 is implemented in a vehicle (not shown), e.g., an automobile, having an internal combustion engine 104. The internal combustion engine 104 defines a cooling jacket (not visible in FIG. 1) as is well known to those skilled in the art of internal combustion engines. The cooling jacket extends to an engine cooling inlet 106 and an engine cooling outlet 108.

An engine cooling apparatus 110 is coupled to the internal combustion engine 104. The engine cooling apparatus 110 includes a radiator 112 having a radiator inlet 114 and a radiator outlet 116. In this embodiment, a first hose 118 connects the engine cooling outlet 108 to the radiator inlet 114. A second hose 120 connects the radiator outlet 116 to the engine cooling inlet 106.

A fluid pump 122 is connected to one of the hoses 118, 120 for pumping fluid, e.g., engine coolant, therethrough. In the embodiment shown in FIG. 1, the fluid pump 122 pumps fluid from the radiator 112 via cooling inlet 106 to the engine 104. The fluid pump 122 is operatively connected to the engine 104 such that mechanical power generated by the engine drives operation of the fluid pump 122, as is readily appreciated by those of ordinary skill in the art.

The electronic sensor assembly 102 senses an environment proximate the vehicle. In one exemplary embodiment, the electronic sensor assembly 102 is a lidar sensor assembly (not separately numbered), such as a flash lidar sensor assembly. The assembly 102, in one exemplary embodiment, includes a light source 200 for generating light and various optics (not shown) for disbursing the light in a field of view. The light source 200 may be a laser, a laser diode, a light emitting diode (“LED”), super luminescent diode. Of course, other devices may be implemented as the light source 200 to generate light. The assembly 102 also may include a detector or detector array 201 to receive light reflected off objects in the field of view.

However, it should be appreciated that the electronic sensor assembly 102 is not limited to lidar-type sensors. In other embodiments (not shown), the electronic sensor assembly 102 may be a camera, a radar assembly, a sonar assembly, one or more photodetectors, etc., as is appreciated by those of ordinary skill in the art.

The temperature regulation system 100 also includes a thermoelectric cooler 202. The thermoelectric cooler 202 may also be referred to as a “Peltier cooler”. The thermoelectric cooler 202 includes a first side 204 and a second side 206. In this embodiment, the sides 204, 206 are formed by generally rectangular-shaped plates (not separately numbered). However, it should be appreciated that other configurations for the sides 204, 206 may alternatively be implemented.

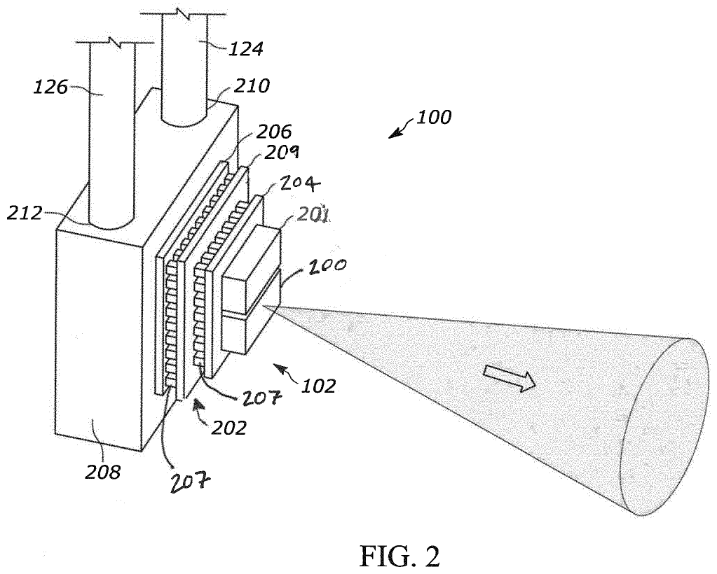

The thermoelectric cooler 202 also includes a plurality of semiconductors 207 disposed between the sides 204, 206. The semiconductors include a plurality of p-type semiconductors and a plurality of n-type semiconductors disposed in an alternating manner. The embodiment shown in FIG. 2 includes an additional plate 209 sandwiched between the two sides 204, 206 with semiconductors disposed between the plate 209 and each of the sides 204, 206.

When a voltage is applied to the semiconductors, a flow of current occurs across the junction of the semiconductors causing a temperature difference. As such, the semiconductors shift heat from one side 204, 206 to the other 206, 204 with the direction of heat transfer being dependent on polarity of current flow through the thermoelectric cooler 202.

The first side 204 of the thermoelectric cooler 202 is affixed or coupled to the electronic sensor assembly 102. As such, heat may be transferred from the electronic sensor assembly 102 to thermoelectric cooler. More particularly, heat is transferred from the first side 204, through semiconductors, and to the second side 206.

However, the thermoelectric cooler 202, while most typically used to cool the electronic sensor assembly 102, may also be used to warm the electronic sensor assembly 102. This is accomplished by changing the polarity of the current flow through the semiconductors, as mentioned above.

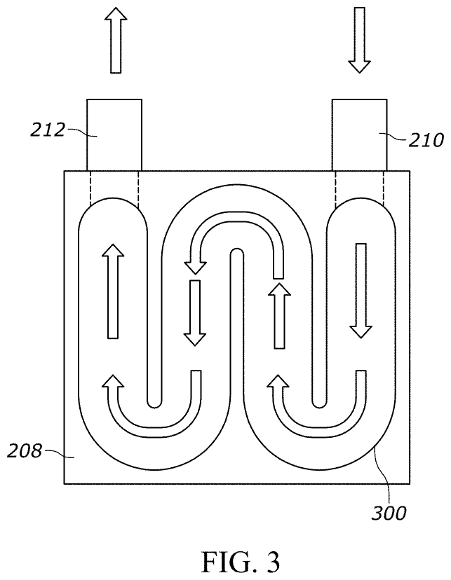

The temperature regulation system 100 further includes a heat exchanger 208 coupled to the second side 206 of said thermoelectric cooler 202. The heat exchanger 208 includes an inlet port 210 for receiving fluid from the engine cooling apparatus 110 of the internal combustion engine 104. The heat exchanger 208 also includes an outlet port 212 for returning fluid to the engine cooling apparatus 110. The heat exchanger 208 may utilize a fluid channel 300, as shown in the exemplary embodiment of FIG. 3, and/or internal tubing.

In the exemplary embodiments, a third hose 124 is coupled to the inlet port 210 and a fourth hose 126 is coupled to the outlet port 212. The third and fourth hoses 124, 126 are also coupled to the cooling system 110 of the vehicle, as described in greater detail below.

The fluid temperature from the engine cooling apparatus 110 that flows through the heat exchanger 208 of the thermoelectric cooler 202 may be greater than the temperature being generated by the assembly 102. Nevertheless, the Peltier effect generated by the thermoelectric cooler 202 is able to cool the assembly 102 while heating the fluid almost negligibly.

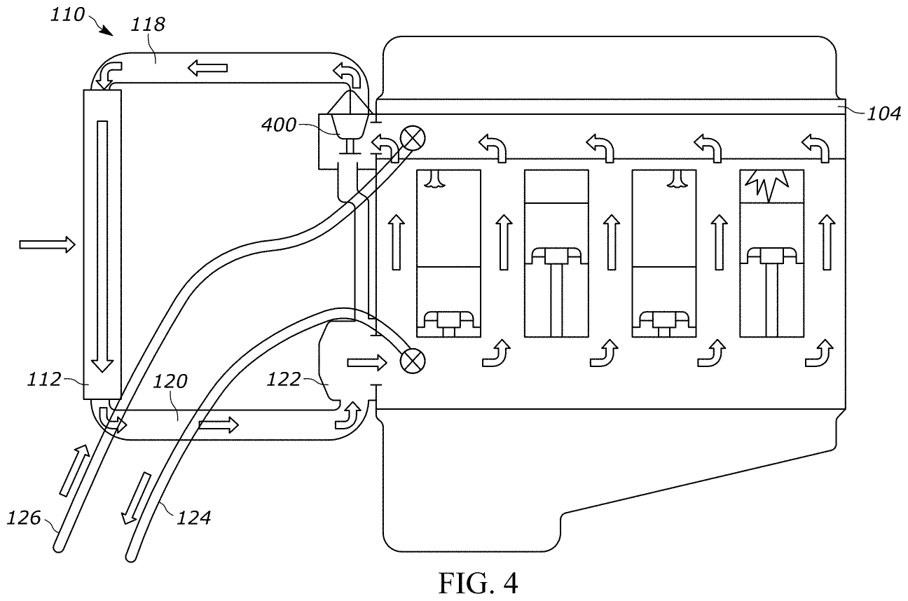

The engine cooling apparatus 110 may include a thermostatic valve 400, as shown in FIG. 4. The thermostatic valve 400 may close to prevent fluid from flowing to the radiator 112 until a predetermined minimum temperature limit is reached. To ensure the flow of fluid to the heat exchanger 208, the third and fourth hoses 124, 126 may be coupled to the engine 104, more specifically to the cooling jacket of the engine 104. As such, when the thermostat 400 is closed, fluid will still flow to and from the heat exchanger 208.

In other embodiments (not shown), the third and fourth hoses 124, 126 may be attached to other locations, including, but not limited to, the radiator 112, the first and second hoses 118, 120, and/or the fluid pump 122.

The present invention has been described herein in an illustrative manner, and it is to be understood that the terminology which has been used is intended to be in the nature of words of description rather than of limitation. Obviously, many modifications and variations of the invention are possible in light of the above teachings. The invention may be practiced otherwise than as specifically described within the scope of the appended claims.

What is claimed is:

1. A temperature regulation system for an automotive electronic sensor assembly, said system comprising:
a thermoelectric cooler coupled to the automotive electronic sensor assembly;
a heat exchanger coupled to said thermoelectric cooler, said heat exchanger including a passage for accommodating fluid from a cooling system of a vehicle.

2. The temperature regulation system as set forth in claim 1, wherein said thermoelectric cooler includes:
a first side coupled to the automotive electronic sensor assembly;
a second side; and
a plurality of semiconductors disposed between said sides.

3. The temperature regulation system as set forth in claim 2, wherein said heat exchanger is coupled to said second side of said thermoelectric cooler.

4. The temperature regulation system as set forth in claim 3 wherein the cooling system is the cooling system of an internal combustion engine, and said heat exchanger includes:
an inlet port for receiving fluid from the cooling system of the internal combustion engine; and
an outlet port for returning fluid to the cooling system of the internal combustion engine.

5. The temperature regulation system as set forth in claim 2 wherein said semiconductors comprises a plurality of p-type semiconductors and n-type semiconductors disposed in an alternating manner.

6. An automotive electronic sensor assembly, comprising:
a light source configured to generate light into a field of view;
a detector configured to receive light reflected off of an object in the field of view; and
a temperature regulation system including
a thermoelectric cooler coupled to the automotive electronic sensor assembly,
a heat exchanger coupled to said thermoelectric cooler and including a passage for accommodating fluid from a cooling system of a vehicle.

7. The automotive electronic sensor assembly as set forth in claim 6, wherein said thermoelectric cooler includes:
a first side;
a second side coupled to said thermoelectric cooler; and
a plurality of semiconductors disposed between said sides.

8. The automotive electronic sensor assembly as set forth in claim 7 wherein said semiconductors comprises a plurality of p-type semiconductors and n-type semiconductors disposed in an alternating manner.

9. The automotive electronic sensor assembly as set forth in claim 6 wherein the cooling system is the cooling system of an internal combustion engine, and said heat exchanger includes:
an inlet port for receiving fluid from the cooling system of the internal combustion engine; and
an outlet port for returning fluid to the cooling system of the internal combustion engine.

10. The automotive electronic sensor assembly as set forth in claim 6 wherein said light source comprises a laser.

11. A vehicle comprising:
an internal combustion engine defining a cooling jacket extending to an engine cooling inlet and an engine cooling outlet;
a cooling system coupled to said internal combustion engine, said cooling system including
a radiator having a radiator inlet and a radiator outlet,
a first hose connecting said engine cooling outlet to said radiator inlet;
a second hose connecting said radiator outlet to said engine cooling inlet; and
a fluid pump connected to one of said hoses for pumping fluid therethrough;
an electronic sensor assembly for sensing an environment proximate said vehicle;
a thermoelectric cooler including
a first side coupled to the electronic sensor,
a second side, and
a plurality of semiconductors disposed between said sides;
a heat exchanger coupled to said second side of said thermoelectric cooler, said heat exchanger including
an inlet port for receiving fluid from the cooling system of the internal combustion engine, and
an outlet port for returning fluid to the cooling system of the internal combustion engine.

12. The vehicle as set forth in claim 11 wherein said electronic sensor assembly includes a light source configured to generate light into a field of view.

13. The vehicle as set forth in claim 12 wherein said electronic sensor assembly includes a detector configured to receive light reflected off of an object in the field of view.

14. The vehicle as set forth in claim 12 wherein said light source comprises a laser.
